(19) United States
(12) Patent Application Publication
(10) Pub. No.: US 2009/0286402 A1
(43) Pub. Date: Nov. 19, 2009

(54) METHOD FOR CRITICAL DIMENSION SHRINK USING CONFORMAL PECVD FILMS

(75) Inventors: Li-Qun Xia, Santa Clara, CA (US); Mihaela Balseanu, Sunnyvale, CA (US); Meiyee Shek, Palo Alto, CA (US); Siyi Li, Fremont, CA (US); Zhenjiang Cui, San Jose, CA (US); Mehul B. Naik, San Jose, CA (US); Michael D. Armacost, San Jose, CA (US); William H. McClintock, Los Altos, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC, Santa Clara, CA (US)

(21) Appl. No.: 12/257,137

(22) Filed: Oct. 23, 2008

Related U.S. Application Data
(60) Provisional application No. 61/052,819, filed on May 13, 2008.

(51) Int. Cl. H01L 21/311

(52) U.S. Cl. 438/703; 257/E21.249

(57) ABSTRACT

A method and apparatus for forming narrow vias in a substrate is provided. A pattern recess is etched into a substrate by conventional lithography. A thin conformal layer is formed over the surface of the substrate, including the sidewalls and bottom of the pattern recess. The thickness of the conformal layer reduces the effective width of the pattern recess. The conformal layer is removed from the bottom of the pattern recess by anisotropic etching to expose the substrate beneath. The substrate is then etched using the conformal layer covering the sidewalls of the pattern recess as a mask. The conformal layer is then removed using a wet etchant.

### CROSS-REFERENCE TO RELATED APPLICATIONS

This application claims benefit of U.S. Provisional Patent Application Ser. No. 61/052,819, filed May 13, 2008, which is herein incorporated by reference.

### BACKGROUND OF THE INVENTION

1. Field of the Invention

Embodiments of the invention relate to methods of semiconductor manufacture. More specifically, embodiments of the invention relate to methods of reducing critical dimension in a semiconductor device.

2. Description of the Related Art

For more than half a century, the semiconductor industry has followed Moore's Law, which states that the density of transistors on an integrated circuit doubles about every two years. Continued evolution of the industry along this path will require smaller features patterned onto substrates. Stack transistors currently in production have dimensions of 50 to 100 nanometers (nm). Devices having dimensions of 45 nm are currently in production, and design efforts are being directed toward devices with dimension of 20 nm and smaller.

As devices shrink to such tiny dimensions, current lithography processes are challenged to create patterns with the required critical dimensions (CD). Patterning tools designed to create vias 100 nm or more wide are not commonly able to create smaller vias.

To avoid having to redesign the current lithography tools, methods are needed to shrink the critical dimension of vias etched into a substrate.

### SUMMARY OF THE INVENTION

Embodiments of the invention provide a method of reducing critical dimension of a recess having sidewalls and a bottom portion formed in a substrate having a field region, comprising applying a conformal layer over the field region, sidewalls, and bottom portion; removing the conformal layer from the bottom portion by a directional etch process to expose the substrate; etching the exposed substrate at the bottom portion; and removing the conformal layer by a wet etch process. The conformal layer has good step coverage, and may be deposited by any means adapted to deposit a conformal layer having high selectivity with respect to etchants used to etch layers beneath the conformal layer.

Other embodiments provide a method of forming a via in a field region of a substrate, comprising patterning a layer formed on a surface of the substrate to form a recess having sidewalls and a bottom portion; reducing the width of the recess by applying a conformal film over the layer; forming a reduced critical dimension area by removing the conformal film from the bottom portion of the recess to expose a portion of the substrate; and etching the reduced critical dimension area to form the via.

Other embodiments provide a method of patterning a dielectric layer formed on a substrate, comprising forming a pattern transfer layer over the dielectric layer; patterning the pattern transfer layer by applying a photoresist, patterning the photoresist, and etching the pattern into the pattern transfer layer to form a recess having a bottom portion; depositing a first conformal layer over the pattern transfer layer; removing the first conformal layer from the bottom portion of the recess to expose the dielectric layer; etching the exposed portion of the dielectric layer to form a narrow recess; removing the pattern transfer layer and the conformal layer; depositing a second conformal layer over the substrate; and removing the second conformal layer from the bottom portion of the narrow recess. Some embodiments provide a double reduction of CD during pattern formation.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a flow diagram illustrating a process according to one embodiment of the invention.

FIGS. 1B-1F are schematic views of a substrate at various stages of the process of FIG. 1A.

FIG. 2A is a flow diagram illustrating a process according to another embodiment of the invention.

FIGS. 2B-2H are schematic views of a substrate at various stages of the process of FIG. 2A.

FIG. 3A is a flow diagram illustrating a process according to another embodiment of the invention.

FIGS. 3B-3D are schematic views of a substrate at various stages of the process of FIG. 3A.

FIG. 4A is a flow diagram illustrating a process according to another embodiment of the invention.

FIGS. 4B-4G are schematic views of a substrate at various stages of the process of FIG. 4A.

FIG. 5A is a flow diagram illustrating a process according to another embodiment of the invention.

FIGS. 5B-5H are schematic views of a substrate at various stages of the process of FIG. 5A.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

The invention generally relates to methods of processing a substrate. Embodiments of the invention provide methods of forming recesses or vias in substrates, wherein the recesses or vias have smaller critical dimensions than would be obtained through conventional lithographic processes.

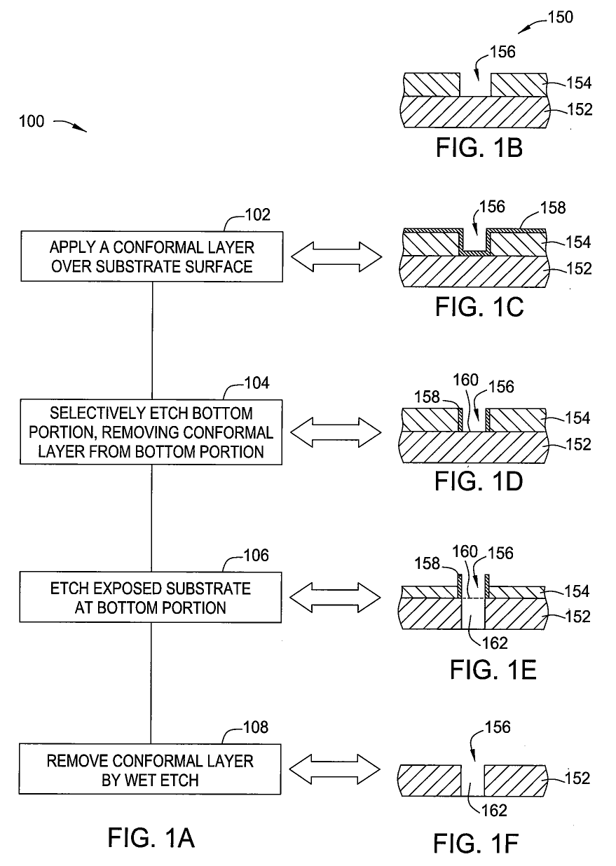

FIG. 1A is a flow diagram describing a method 100 according to one embodiment of the invention. FIGS. 1B-1F are schematic views of a substrate 150 at various stages of the method 100. A substrate such as the substrate 150 having a recess formed therein is provided to a processing chamber. FIG. 1B illustrates the substrate 150 with a feature layer 152 that is to be etched and a recess or opening 156 formed in a pattern transfer layer 154 overlying the feature layer 152. The feature layer 152 may be a dielectric or semiconductor layer of any sort desirous of etching. Pattern transfer layer 154 may be a hard mask layer, an anti-reflective layer, a dielectric layer, or any combination thereof. The recess 156 has sidewalls and a bottom portion that exposes the feature layer 152, and may be used as an etch pattern for subsequent patterning stages.

In box 102 of the method 100, a conformal layer is applied over the substrate surface. FIG. 1C illustrates the conformal layer 158 applied to cover the field region of pattern transfer layer 154 as well as the sidewalls and bottom portion of the recess 156. The conformal layer 158 is preferably formed from a material with a low etch rate in any etchant to be used to etch the feature layer 152. For example, in an embodiment in which the feature layer 152 is an oxide layer to be etched using a fluorine chemistry, the conformal layer 158 may be a nitrogen containing layer, such as a nitride layer. In some embodiments, conformal layer 158 may be a silicon nitride layer, a boron nitride layer, a silicon boronitride layer, a silicon doped boron nitride layer, or a boron doped silicon nitride layer. Additionally, the conformal layer 158 is preferably easy to remove from the substrate, such as by ashing or wet etching.

In some embodiments, the conformal layer is a sacrificial layer to be removed at a later point in processing. As will be described below, in other embodiments, the conformal layer may be a dielectric layer intended to remain as part of the structure and contribute to its final properties. In some embodiments, the conformal layer may be a hermetic layer. In other embodiments, the conformal layer may be a barrier layer or an anti-reflective layer. The conformal layer will preferably have step coverage between about 80% and about 120%.

As will be seen below, the conformal layer 158 applied in box 102 will serve as an etching mask, and the thickness of conformal layer 158 will define the critical dimension of the pattern etched into layer 152. For example, if the recess 156 is 500 Å wide, a conformal layer 50 Å wide will reduce the width of the recess 156 to 400 Å. A subsequent etching sequence will, in turn, generate a pattern 400 Å wide in the feature layer 152. Such a process may be useful in generating patterns having critical dimension smaller than the capability of a particular lithography apparatus.

A conformal layer such as the conformal layer 158 may be deposited by any of the known methods for depositing conformal layers on substrates. Examples of such methods include, but are not limited to, chemical vapor deposition (CVD), plasma enhanced CVD (PECVD), atomic layer epitaxy (ALE), atomic layer deposition (ALD), and plasma enhanced ALD (PEALD). A silicon nitride conformal layer may be deposited by using an ALD or PEALD process wherein pulses of a precursor that may be any of silane oligomer such as silane or disilane, a lower alkyl silane such as methyl- or dimethylsilane, or a lower alkoxysilane, silanol, or silazane are provided to a reactor containing the substrate, alternating with a nitrogen-containing compound such as nitrogen gas (N₂), ammonia (NH₃), nitrous oxide (N₂O), or hydrazine (N₂H₂). A carrier gas is often used to facilitate providing the precursors and purging the reactor. At suitable conditions, the precursors react with the substrate surface to produce layers of a deposited product, which grow uniformly over the surface of the substrate. A desired thickness is reached by repeating the process as necessary. Similarly, a boron nitride layer may be produced in an ALD or PEALD process using a borane oligomer, such as borane or diborane, alternately with a nitrogen containing precursor such as N₂, NH₃, N₂O, or N₂H₂. Doping may be accomplished by using a gas mixture of boron and silicon precursors in proportion approximate to the level of doping desired.

In box 104 of the method 100, the portion of the conformal layer covering the bottom portion of the recess is etched away to expose a portion of the feature layer 152 underneath. FIG. 1D illustrates the substrate having the conformal layer 158 removed from the bottom portion 160 of the recess 156. The conformal layer 158 may be removed from the bottom portion 160 of the recess 156 through a selective etching process. In some embodiments, the selective etching process may be a directional or anisotropic etching process designed to etch material from horizontal surfaces of the substrate only. Such processes may feature a plasma etchant with an electrical bias applied to the substrate to encourage ions in the plasma to accelerate toward the substrate surface. In such processes, the accelerated ions will generally travel deep into the recess 156 before curving toward a sidewall, with the result that a vast majority of reactive species impact the bottom portion 160 of the recess 156. At the same time, such a process may also result in substantial removal of the conformal layer 158 from the field region of the pattern transfer layer 154. Reactive ion etching using fluorine and oxygen ions is one example of a selective etching process useful for practicing embodiments of the invention. Other etching methods, such as etching by non-reactive ions, may also be used.

After exposing a portion of the feature layer 152 beneath the conformal layer 158, the feature layer 152 may be etched in box 106. FIG. 1E illustrates the substrate at this stage of the method 100. Portions of the conformal layer 158 remaining on the sidewalls of recess 156 reduce the width of recess 156 and the portion of the feature layer 152 exposed to etchant. If the conformal layer 158 is formed from a material having high etch selectivity with respect to the etchant used to etch the feature layer 152, the conformal layer 158 will etch slowly or not at all during box 106, leaving a reduced CD via 162 etched in the feature layer 152. Etching of the feature layer 152 may be performed by any method known to etch the material of which the feature layer 152 is formed, but will preferably be performed by a process that will not etch the conformal layer 158. The pattern transfer layer 154 may also be partially etched away at the same time, leaving a reduced thickness of the layer 154. A directional etch, such as etching under bias using reactive or non-reactive ions as described elsewhere herein, may be advantageous for preserving the remnants of the conformal layer 158 while etching the dielectric layer 152.

The conformal layer 158 may be removed in box 108 to leave a substrate with a reduced CD via ready for subsequent processing, as shown in FIG. 1F. The pattern transfer layer 154 is also generally removed by etching or oxidative means. The reduced CD via 162 is narrower than would be obtainable through conventional lithography.

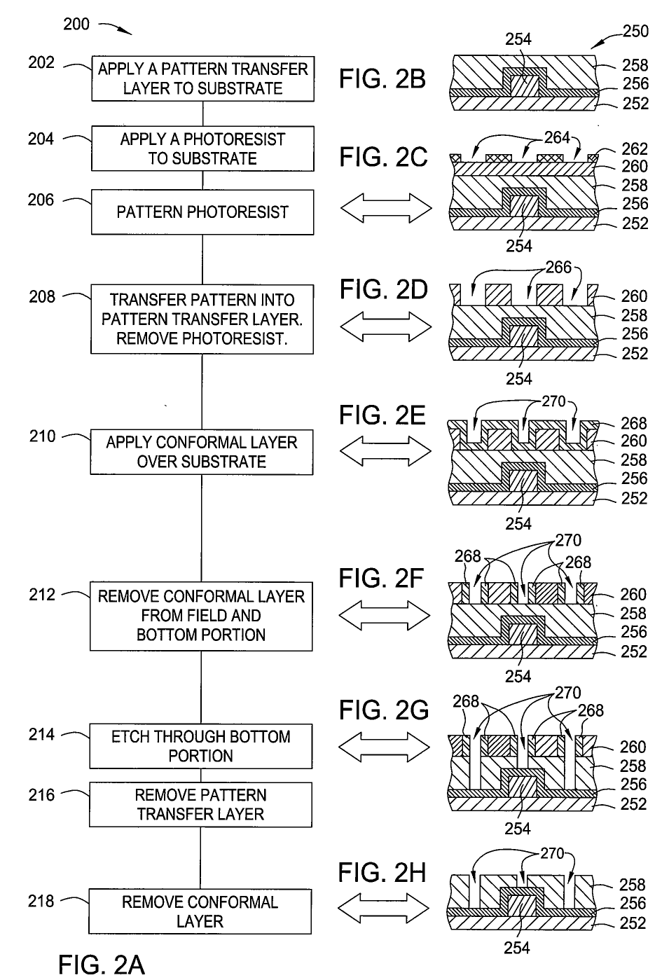

Other embodiments of the invention provide a method of forming a via in a field region of a substrate. FIG. 2A is a flow diagram describing a method 200 according to one embodiment of the invention. A substrate to be etched is positioned in a process chamber. FIG. 2B is a schematic view of a substrate 250 to be treated according to the method 200. An exemplary substrate such as substrate 250 may have a bottom layer 252, a stack structure 254, a protective layer 256, and an insulating or dielectric layer 258.

In box 202, a pattern transfer layer is applied to the substrate. The pattern transfer layer will serve as an etch mask for subsequent etch sequences. The pattern transfer layer may be a dielectric layer, anti-reflective layer, or barrier layer, and may possess more than one such property. An amorphous carbon layer, comprising a mixture of sp³ (diamond-like), sp² (graphitic)- and sp¹(pyrrolitic)-hybridized carbon atoms, formed from a CVD process using hydrocarbon precursors, may be useful as a pattern transfer layer. An exemplary amorphous carbon layer is the APF® Advanced Patterning Film produced by the PRODUCER® SE and GT PECVD platforms available from Applied Materials, Inc., of Santa Clara, Calif. A substrate to be etched is generally disposed in a processing chamber to form the pattern transfer layer. The substrate may be disposed on a substrate support, which may serve as an electrode for generating a capacitatively coupled plasma, and which may be adapted to control the temperature of the substrate. In alternate embodiments, the substrate support may serve to apply an electrical bias to the substrate for directional deposition of a plasma. A capacitatively coupled plasma may also be generated inside the process chamber by deploying electrodes other than the substrate support, such as side plates, showerhead electrodes, diffusion plates, and the like. The sidewalls of the chamber may serve as plasma generation electrodes. In still other embodiments, a plasma may be generated by inductive coupling through re-entrant tubes fitted with inductive coils and disposed at the top of the chamber Finally, in some embodiments, a plasma may be generated remotely and provided to the chamber. Details of an exemplary plasma chamber for forming a pattern transfer layer may be found in U.S. Pat. Nos. 5,855,681 and 6,495,233.

Amorphous carbon is an exemplary pattern transfer layer. Also known as a “hard mask,” to distinguish from the “soft” photoresist generally used to establish the pattern as further described below, the amorphous carbon pattern transfer layer may be formed by providing a carbon source to a processing chamber having a substrate disposed therein. The carbon source may be propylene or acetylene in some embodiments, but is preferably a precursor having suitable vapor pressure and ionization potential for easy activation. RF power is generally applied to ionize the carbon precursor into a reactive plasma. In some embodiments, a voltage may be applied to the substrate to accelerate the reactive ions toward the surface of the substrate, encouraging deposition thereon.

A photoresist layer is formed on the pattern transfer layer in box 204. The photoresist is generally a polymer material sensitive to a certain wavelength of electromagnetic radiation, and may be applied through a spin coating process or a CVD process. In some embodiments, the photoresist is a carbon-based polymer sensitive to ultraviolet light, such as a phenolic resin, an epoxy resin, or an azo napthenic resin. The photoresist layer may be a positive or a negative photoresist. Preferred positive photoresists may be selected from the group consisting of a 248 nm resist, a 193 nm resist, a 157 nm resist, and a phenolic resin matrix with a diazonapthoquinone sensitizer. Preferred negative photoresists may be selected from the group consisting of poly-cis-isoprene and poly-vinylcinnamate. In some embodiments, the photoresist layer may further comprise a bottom anti-reflective coating (BARC) layer, and the BARC layer and the photoresist layer may be deposited by a spin-on process.

The photoresist layer is patterned in box 204, and the pattern developed. FIG. 2C illustrates the substrate 250 at this stage of the process. A pattern transfer layer 260 has been formed over the dielectric layer 258. A photoresist layer 262 overlays the pattern transfer layer 260, and exhibits pattern openings 264 that expose the pattern transfer layer 260 beneath.

In the embodiment of FIGS. 2B-2H, the pattern provided by etching the photoresist exhibits multiple openings 264. The openings 264 are ultimately used to form contact vias for the gate stack and the source and drain junctions of the device 254. Use of a reduced CD pattern for forming the contact vias is advantageous for reducing capacitative interaction, or cross-talk, between the contacts. Reducing the CD of the vias increases the distance between them, which reduces capacitative coupling of the contacts formed in the vias.

The pattern is transferred into the pattern transfer layer in box 208. The pattern may be etched into the pattern transfer layer by any suitable process. In an exemplary embodiment in which the pattern transfer layer is an amorphous carbon layer, the pattern may be etched using a plasma etching process incorporating a combination of O₂ and N₂ or a combination of CH₄, N₂, and O₂. FIG. 2D shows the substrate 250 at this stage of the method 200. Pattern transfer layer 260 has been etched to form openings or recesses 266. The width of the openings 266 has been determined by the width of the pattern openings 264 written into the photoresist layer 262. The photoresist layer has been removed in this stage as well. In some embodiments, carbon atoms may predominate in both the photoresist and the pattern transfer layer, such that substantially the same etch chemistry may be used to remove the photoresist and transfer the etch pattern.

A conformal layer is formed over the substrate in box 210. FIG. 2E illustrates the substrate 250 at this stage of the process. A conformal layer 268 is shown overlying the substrate, forming reduced width recesses 270. A conformal film may be formed by any process suitable for forming conformal films. The conformal film uniformly reduces the width of the openings 266. A conformal film will preferably have step coverage of between about 80% and about 120%, and will be formed from a material having a low etch rate with respect to etchants used to etch the underlying dielectric layer 258. In an exemplary embodiment wherein the dielectric layer 258 is an oxide layer, such as a porous silicon oxycarbide low-k or ultra low-k dielectric layer, the conformal film may be a nitrogen containing film. Silicon nitride, boron nitride, and silicon boronitride are exemplary films suitable for this method. A conformal film may be deposited by processes such as atomic layer epitaxy (ALE), atomic layer deposition (ALD), and chemical vapor deposition (CVD). These processes may be plasma enhanced.

Generally, silicon nitride is deposited as a layer or film with the empirical, chemical formula, SiNₓ. Fully nitrided silicon nitride may have the chemical formula Si₃N₄, such that the N:Si ratio (atomic) is about 1.33. However, less nitrided silicon nitride material may be formed with N:Si ratio as low as about 0.7. Therefore, silicon nitride materials have a N:Si ratio from about 0.7 to about 1.33, preferably, from about 0.8 to about 1.3. Silicon nitride materials may contain other elements, besides silicon and nitrogen, such as hydrogen, carbon, oxygen and/or boron. In some embodiments, the hydrogen concentration in the silicon nitride material is about 8 weight percent (wt %) or greater. The carbon concentration in the silicon nitride material may be from about 3 atomic percent (at %) to about 15 at %. Silicon nitride materials include silicon nitride (SiNₓ), silicon oxynitride (SiOₓN_{y}), silicon carbon nitride (SiCₓN_{y}), and silicon carbon oxynitride (SiCₓO_{y}N_{z}). Silicon nitride materials may be formed with varying stoichiometry and composition by controlling the process conditions.

Boron nitride films may also be formed with stoichiometry varying around the ratio of 1:1. Films having composition BₓN_{y} may be formed by processes described herein, with the ratio of x:y varying between about 0.9 and about 1.1. Composition of the boron nitride film may be adjusted by controlling process conditions.

Some films may contain silicon, boron, and nitrogen. In some embodiments, a boron-doped silicon nitride film may be formed. In other embodiments, a silicon-doped boron nitride film may be formed. In still other embodiments a silicon boronitride film, with silicon, boron, and nitrogen in approximately stoichiometric ratios (i.e. 1:1:1), may be formed. In other embodiments, any of the films described above may also be doped with, or otherwise contain, hydrogen, carbon, halogens such as chlorine or fluorine, oxygen, or other dopants.

In an ALE or ALD process, chemical precursors are provided to a process chamber sequentially, and the chamber purged between steps. In an exemplary process for depositing a boron nitride conformal layer, a boron precursor such as borane (BH₃), another borane oligomer such as diborane (B₂H₆), borazine (B₃N₃H₆), an alkyl borazine, trimethylborine (B(CH₃)₃), or BCl₃ may be provided to a process chamber. A carrier gas may be used to facilitate pulsing precursors to the process chamber. The carrier gas may be a non-reactive gas, such as helium (He), argon (Ar), nitrogen (N₂), or xenon (Xe). The carrier gas may flow continuously, with precursors pulsed into the carrier gas stream, or it may flow intermittently with pulsed precursors. Following deposition of boron precursors, the chamber is purged, either by a pulse of purge gas or a continuous flow of non-reactive carrier gas. A second precursor containing nitrogen, such as nitrogen gas (N₂), ammonia (NH₃), nitrous oxide (N₂O), or hydrazine (H₂N₂) is then pulsed into the chamber and allowed to react. A purge step follows the nitrogen step. This cycle may be repeated until the desired thickness of the deposited film is reached. To deposit a silicon nitride film, instead of a boron precursor, a silicon precursor such as a lower silane, siloxane, silanol, or silazane, or alkyl, phenyl, and amino derivatives thereof may be used. Silane (SiH₄) and methyl silane (MeSiH₃) are examples. Additionally, cyclic derivatives, such as substituted cyclosiloxanes and cyclosilazanes, and halogen derivatives may also be used. In some embodiments, the conformal layer may additionally be doped with atoms selected from the group consisting of C, F, N, O, Si, Cl, and H.

In some embodiments, more than two precursors may be used. To deposit an exemplary silicon boronitride conformal layer, for example, a silicon containing precursor such as those listed above may be provided to the process chamber to deposit a silicon containing species. After a purge step, a boron precursor as described above may be provided to add boron to the layer, and then a nitrogen precursor as described above may be provided to add nitrogen to the layer. The three-stage cycle may be repeated as necessary to build a conformal layer having the desired chemistry and thickness.

In an ALD process for depositing a conformal film such as that described herein, a substrate may be subjected to a precleaning process and a surface preparation prior to commencement of the ALD process. These preparations remove any native oxide from the upper surface of the substrate and terminate the surface with functional groups designed to facilitate the ALD process. Functional groups attached or formed on the surface of the substrate include hydroxyls (OH), alkoxy (OR, where R=Me, Et, Pr, or Bu), haloxyls (OX, where X═F, Cl, Br, or I), halides (F, Cl, Br, or I), oxygen radicals and amidos (NR or NR₂, where R═H, Me, Et, Pr, or Bu). The precleaning process may expose the substrate to a reagent, such as NH₃, B₂H₆, SiH₄, Si₂H₆, H₂O, HF, HCl, O₂, O₃, H₂O₂, H₂, atomic-H, atomic-N, atomic-O, alcohols, amines, plasmas thereof, derivatives thereof, or combinations thereof. The functional groups may provide a base for an incoming chemical precursor to attach on the upper surface of the substrate. In certain embodiments, the precleaning process may expose the upper surface of the substrate to a reagent for a period from about 1 second to about 2 minutes. In certain embodiments, the exposure period may be from about 5 seconds to about 60 seconds. Precleaning processes may also include exposing the surface of the substrate to an RCA solution (SC1/SC2), an HF-last solution, peroxide solutions, acidic solutions, basic solutions, plasmas thereof, derivatives thereof or combinations thereof. In some embodiments, a substrate may be immersed in a hydrofluoric acid bath for about 2 to about 15 minutes. In one exemplary embodiment, a substrate may be immersed in a 2% hydrofluoric acid bath for about 2 minutes. In some embodiments, pre-cleaning may be accomplished in a batch cleaning system or in a single substrate cleaning system. One example of a single substrate cleaning system is the OASIS CLEAN® system available from Applied Materials, Inc., of Santa Clara, Calif.

In certain embodiments where a wet-clean process is performed to clean the substrate surface, the wet-clean process may be performed in a MARINER™ wet-clean system or a TEMPEST wet-clean system, available from Applied Materials, Inc. Alternatively, the substrate may be exposed to water vapor derived from a WVG system for about 15 seconds.

The ALE or ALD process may be assisted by application of RF power to form a plasma. The RF power may be continuous throughout the pulsing and purging steps, or it may be applied selectively. Generally, an inductively coupled or weak capacitatively coupled plasma is preferred, in order to avoid highly directional deposition.

In a thermal CVD process for depositing a boron nitride film, a boron precursor and a nitrogen precursor may each be provided to a processing chamber at a flow rate between about 5 sccm and about 50 slm, such as between about 10 sccm and about 1 slm. In one embodiment, a non-reactive gas, such as a carrier gas, may also be provided at a flow rate between about 5 sccm and about 50 slm, such as between about 10 sccm and about 1 slm. The chamber may be maintained at a pressure of between about 10 mTorr and about 760 Torr, such as between about 2 Torr and about 20 Torr, and the substrate at a temperature of between about 100° C. and about 1000° C., such as between about 300° C. and about 500° C.

In a PECVD process for depositing a boron nitride film, RF power may be applied to activate the precursors. The RF power may be provided at a power level between about 2 W and about 5000 W, such as between about 30 W and about 1000 W, at a single low frequency of between about 100 kHz up to about 1 MHz, for example, about 300 kHz to about 400 kHz, or at a power level between about 2 W and about 5000 W, such as between about 30 W and about 1000 W, at a single high frequency of greater than about 1 MHz, such as greater than about 1 MHz up to about 60 MHz, for example, 13.6 MHz. Alternatively, the RF power may be provided at a mixed frequency including a first frequency between about 100 kHz up to about 1 MHz, for example, about 300 kHz to about 400 kHz, at a power level between about 2 W and about 5000 W, such as between about 30 W and about 1000 W, and a second frequency of greater than about 1 MHz, such as greater than about 1 MHz up to about 60 MHz, for example, 13.6 MHz, at a power level between about 2 W and about 5000 W, such as between about 30 W and about 1000 W.

In a further embodiment in which the boron-containing precursor and the nitrogen-containing precursor are introduced simultaneously, a silicon-containing precursor may also be introduced into the chamber with the boron-containing precursor and the nitrogen-containing precursor to form a SiBN layer. Exemplary processing conditions for depositing a SiBN layer include introducing the precursor at 60 sccm SiH₄, 600 sccm NH₃, 1000 sccm N₂, 100-1000 sccm B₂H₆, generating a plasma at 100 W RF power at 13.6 MHz, while maintaining chamber conditions at a chamber pressure of 6 Torr, and a spacing of 480 mils. Optionally, the SiBN layer may be UV cured for 10 minutes at 400° C.

In an ALD process for depositing a boron nitride layer, the layer may be deposited at a rate of 20 Å per cycle using diborane and nitrogen as precursors in a ratio of between about 4:1 and about 6:1, such as about 5:1. For example, 400 sccm of diborane and 2000 sccm of nitrogen may be provided at a chamber pressure of 6 Torr and a spacing of 480 mils for 5 seconds/cycle, and the resulting layer treated with a plasma process to incorporate nitrogen into the layer and form a boron nitride layer, wherein the plasma process comprises using 100 sccm of ammonia and 2000 sccm of nitrogen for 10 seconds/cycle with 300 W of RF power at 13.6 MHz.

Conformal deposition of silicon and nitrogen containing layers may be carried out according to various processes. In some processes, a substrate surface may be exposed to a silicon precursor and an ammonia-free reactant. Silicon precursors may include alkylaminosilanes such as bis(tertiaryamino)silane (BTBAS), and the ammonia-free reactant may be a compound such as hydrogen, silanes, boranes, germanes, alkyls, amines, or hydrazines. Exposure to the reactants may be in a thermal CVD process, a pulsed CVD process, or an ALD process, and may be activated into a plasma.

In one process, a silicon precursor and a reactant are sequentially pulsed into a process chamber having a substrate disposed therein to accomplish an ALD process. The silicon precursor is administered into the process chamber with a flow rate from about 1 sccm to about 300 sccm, preferably from about 10 sccm to about 100 sccm. For example, BTBAS may have a flow rate from about 13 sccm to about 130 sccm, which is equivalent to a rate from about 0.1 g/min to about 1.0 g/min depending on the BTBAS partial pressure and the exposed surface area. The reactant is administered into the process chamber with a flow rate from about 100 sccm to about 3,000 sccm or higher, preferably greater than about 500 sccm, such as from about 500 sccm to about 3,000, more preferably, from about 1,000 sccm to about 2,000 sccm. The pulses of silicon precursor, reactant or purge gas independently have a time duration from about 0.05 seconds to about 10 seconds, preferably from about 0.1 seconds to about 1 second, for example, about 0.5 seconds. Each pulse is usually followed by a time delay to allow the pulsed precursor to adhere to the substrate, with a purge gas such as nitrogen or argon flowing continuously through the reaction zone or pulsed through after the time delay.

Useful silicon precursors for forming a conformal silicon nitride layer generally contain nitrogen, such as an aminosilane. Specific aminosilanes that are useful silicon precursors are alkylaminosilanes with the chemical formula of (RR′N).sub.4-nSiH.sub.n, wherein R and R′ are independently hydrogen, methyl, ethyl, propyl, butyl, pentyl or aryl and n=0, 1, 2 or 3. In one embodiment, R is hydrogen and R′ is an alkyl group, such as methyl, ethyl, propyl, butyl or pentyl, for example, R′ is a butyl group, such as tertiarybutyl and n is 2. In another embodiment, R and R′ are independently alkyl groups, such as methyl, ethyl, propyl, butyl and pentyl or an aryl group. Silicon precursors useful for the deposition processes described herein include (.sup.tBu(H)N).sub.3SiH, (.sup.tBu(H)N).sub.2SiH.sub.2, (.sup.tBu(H)N)SiH.sub.3, (.sup.iPr(H)N).sub.3SiH, (.sup.iPr(H)N).sub.2SiH.sub.2, (.sup.iPr(H)N)SiH.sub.3, and derivatives thereof. Preferably, the silicon precursor is bis(tertiarybutylamino)silane ((.sup.tBu(H)N).sub.2SiH.sub.2 or BTBAS). In other embodiments, the silicon precursor may be an alkylaminosilane with the chemical formula of (RR′N).sub.4-nSiR″.sub.n, wherein R and R′ are independently hydrogen, methyl, ethyl, propyl, butyl, pentyl, or aryl, R″ is independently hydrogen, alkyl (e.g., methyl, ethyl, propyl, butyl or pentyl), aryl or halogen (e.g., F, Cl, Br or I) and n=0, 1, 2 or 3.

In processes for forming conformal silicon and nitrogen containing layers in single wafer processing chambers using BTBAS as the silicon precursor, the ratio of BTBAS to reactant is generally at least about 10, and preferably between about 10 and about 100, for example between about 30 and about 50. The ratio may be lower for batch processing chambers. The substrate may be maintained at a temperature between about 500° C. and about 800° C., and the chamber maintained at a pressure between about 10 Torr and about 760 Torr, for example about 250 Torr. In an alternate embodiment, the silicon precursor and the reactant may be pulsed sequentially into the chamber to accomplish an ALD process.

In some embodiments, deposition of a conformal layer containing silicon and nitrogen may be facilitated by exposing the substrate to an energy beam derived from a UV source during a pretreatment process, and exposing the substrate to a deposition gas containing an aminosilane and the energy beam during a deposition process. The energy beam may be generated using an excimer laser, such as a Xe-excimer laser. One example of a useful Xe-excimer laser is the XERADEX® 20, available from Osram Sylvania, located in Danvers, Mass.

A substrate may be exposed to the energy beam in a pre-treatment process to remove native oxide from the surface of the substrate. The substrate may be pretreated with an energy beam generated by direct photoexcitation system to remove the native oxides from the substrate surface prior to depositing a silicon nitride material. A process gas may be exposed to the substrate during the pretreatment process. The process gas may contain argon, nitrogen, helium, hydrogen, forming gas, or combinations thereof. The pretreatment process may last for a time period within a range from about 2 minutes to about 10 minutes to facilitate native oxide removal during a photoexcitation process. Also, the substrate may be heated during photoexcitation to a temperature within a range from about 100.degree. C. to about 800.degree. C., preferably, from about 200.degree. C. to about 600.degree. C., and more preferably, from about 300.degree. C. to about 500.degree. C., to facilitate native oxide removal during process 100. The energy beam may be a photon beam having photon energy within a range from about 2 eV to about 10 eV, and may produce UV radiation having a wavelength within a range from about 126 nm to about 351 nm.

In some embodiments, an energy delivery gas may be provided during the photoexcitation process. The energy delivery gas may be neon, argon, krypton, xenon, argon bromide, argon chloride, krypton bromide, krypton chloride, krypton fluoride, xenon fluorides (e.g., XeF₂), xenon chlorides, xenon bromides, fluorine, chlorine, bromine, excimers thereof, radicals thereof, derivatives thereof, or combinations thereof. In some embodiments, the process gas may also contain nitrogen gas (N₂), hydrogen gas (H₂), forming gas (e.g., N₂/H₂ or Ar/H₂) besides at least one energy delivery gas. In other embodiments, the process gas may contain a cyclic aromatic hydrocarbon. Monocyclic aromatic hydrocarbons and polycyclic aromatic hydrocarbons that are useful during a pretreatment process include quinone, hydroxyquinone (hydroquinone), anthracene, naphthalene, phenanthracene, derivatives thereof, or combinations thereof. In another example, the substrate may be exposed to the process gas containing other hydrocarbons, such as unsaturated hydrocarbons, including ethylene, acetylene (ethyne), propylene, alkyl derivatives, halogenated derivates, or combinations thereof. In another example, the organic vapor may contain alkane compounds during the pretreatment process.

Silicon precursors that may be used to produce a silicon nitride material by the UV-assisted chemical vapor deposition at sufficiently high deposition rates while at a low temperatures include compounds having one or more Si—N bonds or Si—Cl bonds, such as bis(tertbutylamino)silane (BTBAS or (tBu(H)N)₂SiH₂) or hexachlorodisilane (HCD or Si₂Cl₆). Silicon precursors having preferred bond structures have the chemical formulas: R₂NSi(R′₂)Si(R′₂)NR₂ (aminodisilanes), (1) R₃SiN₃ (silylazides), or (II)R′₃SiNRNR₂ (silylhydrazines). (III) R and R′ may be one or more functional groups independently selected from the group of a halogen, an organic group having one or more double bonds, an organic group having one or more triple bonds, an aliphatic alkyl group, a cyclical alkyl group, an aromatic group, an organosiylyl group, an alkylamino group, or a cyclic group containing N or Si, or combinations thereof. Examples of suitable functional groups on silicon precursors include chloro (—Cl), methyl (—CH₃), ethyl (—CH₂CH₃), isopropyl (—CH(CH₃)₂), tertbutyl (—C(CH₃)₃), trimethylsilyl (—Si(CH₃)₃), pyrrolidine, or combinations thereof. It is believed that many of the silicon precursors or the nitrogen precursors described herein may decompose or disassociate at a low temperature, such as about 550.degree. C. or less.

Other examples of suitable silicon precursors for a UV-excited deposition process include silylazides R₃—SiN₃ and silylhydrazine class of precursors R₃SiNRNR₂, linear and cyclic with any combination of R groups. The R groups may be H or any organic functional group such as methyl, ethyl, propyl, butyl, and the like (CₓH_{y}). The R groups attached to Si can optionally be another amino group NH₂ or NR₂. One benefit of using a silicon-nitrogen precursor is that silicon and nitrogen are simultaneously delivered while avoiding the presence of chlorine to yield films with good step coverage and minimal pattern dependence (so-called pattern loading) without the undesirable ammonium chloride particle formation problematic to other conventions Si—N film precursors. Examples of specific silylazide compounds include trimethylsilylazide ((CH₃)₃SiN₃) (available from United Chemical Technologies, located in Bristol, Pa.) and tris(dimethylamine)silylazide (((CH₃)₂N)₃SiN₃). An example of a specific silylhydrazine compound is 1,1-dimethyl-2-dimethylsilylhydrazine ((CH₃)₂HSiNHN(CH₃)₂). In another embodiment, the silicon-nitrogen precursor may be at least one of (R₃Si)₃N, (R₃Si)₂NN(SiR₃)₂ and (R₃Si)NN(SiR₃), wherein each R is independently hydrogen or an alkyl such as methyl, ethyl, propyl, butyl, phenyl, or combinations thereof. Examples of suitable silicon-nitrogen precursor include trisilylamine ((H₃Si)₃N), (H₃Si)₂NN(SiH₃)₂, (H₃Si)NN(SiH₃), or derivatives thereof.

The conformal layer 268, which may also be a conformal film, reduces the width of the opening 266 by the thickness of the film. Thus, the thickness of the conformal layer 268 may be derived from the desired reduction in width. For example, if the opening 266 is 500 Å in width, it may be reduced to a recess 400 Å in width by formation of a conformal layer 50 Å thick. This reduction in width is useful for manufacturing features smaller than the capability of current lithography tools.

A portion of the conformal layer is removed in box 212, continuing the method 200 of FIG. 2A. Removal of the conformal layer may be by an etching process, and is preferably anisotropic to avoid etching the film from the sidewalls of the reduced width recess. An exemplary process useful for anisotropic etching in such a setting is reactive ion etching. An etchant is provided to a process chamber, which may be the same chamber as that used to create the conformal layer, or it may be a different chamber. The etchant is activated by application of RF power to form a gas mixture comprising reactive ions. An electrical bias may be applied to the substrate to accelerate the reactive ions toward the substrate surface. Those ions that penetrate the reduced width recess will travel deep into the recess before curving toward the sidewall. The majority of such ions will impact the bottom portion of the recesses 270, thus etching the conformal layer from the bottom portion of the recesses 270. Those ions that do not penetrate the recesses 270 will impact the field region of the substrate, and will etch away the conformal layer 268 from the field region. FIG. 2F illustrates a substrate at this stage of the method 200.

For an embodiment in which the conformal layer is a silicon nitride layer, a boron nitride layer, or a silicon boronitride layer, the reactive ions may be formed by providing a halogen containing precursor to the process chamber containing the substrate. Various halides of carbon, sulfur, and nitrogen may be used to etch these materials. Examples include CF₄, SF₆, NF₃, and CHF₃. Chlorine containing analogs will also etch these layers at somewhat slower rates.

In one embodiment, for example, etchant SF₆ may be provided to a processing chamber having a substrate disposed therein. The etchant may be provided at a flow rate of between about 20 sccm and about 1000 sccm, such as between about 100 sccm and 500 sccm, for example about 300 sccm. A non-reactive carrier gas such as helium, argon, neon, or xenon may be provided. The substrate may be maintained at a temperature of between about 50° C. and about 500° C., such as between about 200° C. and about 400° C., for example about 300° C. The chamber may be maintained at a pressure between about 1 mTorr and about 10 Torr, such as between about 1 Torr and about 5 Torr, for example about 2 Torr. RF power of between about 200 W to about 5000 W may be applied at a high single frequency of 13.56 MHz, or at a low single frequency of between about 100 kHz and about 600 kHz, such as about 400 kHz, or at a mixed frequency having a first frequency of about 400 kHz and a second frequency of about 13.56 MHz. The RF power may be capacitatively or inductively coupled. An electrical bias may be applied to the substrate by applying a voltage to the substrate support or the gas distribution plate with a power range between about 100 W and about 1000 W, such as about 500 W. The RF power dissociates fluoride ions F⁻ from SF₆ molecules, and the electrical bias accelerates the ions toward the substrate surface. Ions accelerate toward the field region and into the recess. Ions that penetrate the recess generally travel to the bottom and etch the conformal layer at the bottom of the recess.

In an alternate embodiment, the bottom portion of the recesses 270 may be etched using non-reactive ions. A noble gas, such as argon, helium, neon, or xenon, may be ionized into a plasma and accelerated toward the surface of the substrate by a voltage bias applied to the substrate. The energetic ions thus created will then impact the field region of the substrate and the bottom portion of the reduced width recess, eroding the conformal layer from the substrate by high-energy impact.

In box 214, the underlying dielectric layer 258 is etched by known processes using the reduced width recesses as an etch mask. FIG. 2G shows a substrate at this stage of the method 200. The remnant of the conformal layer 268 is etched slowly, or not at all, by the etch chemistry used to etch the dielectric layer 258. Thus, the conformal layer 268 defines the width of the etched opening. This method may be used to form openings much smaller than the capability of current lithography tools, such as less than 50 nm in width. A directional etch method incorporating reactive or non-reactive ions under an electrical bias may be useful for etching the dielectric layer 258 while leaving the remnants of the conformal layer 268 undisturbed.

The pattern transfer layer 260 is removed in box 216. This may be accomplished through any process adapted to remove layers having the composition of layer 260. In an exemplary embodiment wherein pattern transfer layer 260 is a carbon containing layer, such as an amorphous carbon layer, the pattern transfer layer 260 may be removed by oxidation. A preferred oxidation method is to attack the layer using an oxygen plasma. This method is preferred because it removes carbon layers at a rapid rate. Other oxidation methods may be used, however, such as thermal oxidation.

Following removal of the pattern transfer layer 260, any remaining vestige of the conformal layer 268 is removed in box 218. FIG. 2H shows a substrate at this stage of the method 200. Removal of the conformal layer 268 may be accomplished using any process adapted to remove layers having the composition of conformal layer 268. In an exemplary embodiment wherein the conformal layer 268 is a boron and nitrogen containing layer, the conformal layer 268 may be conveniently removed using an aqueous solution, which may be an oxidizing solution such as a sulfuric peroxide mixture (SPM) known in the art. A rinse of this nature generally will not etch an oxide-based dielectric. Silicon and nitrogen containing layers may be removed using an acidic solution, such as a hydrogen fluoride or phosphoric acid solution.

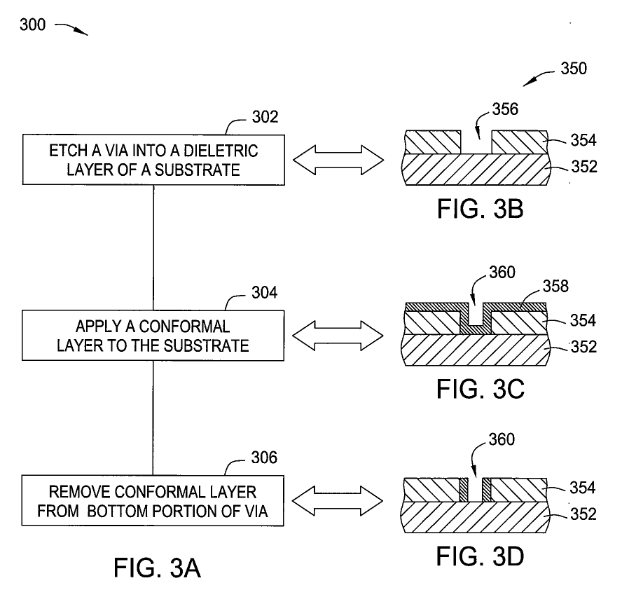

Embodiments of the invention also provide a method of forming a via having reduced CD in a field region of a substrate. FIG. 3A is a flow diagram illustrating a process according to another embodiment of the invention. FIGS. 3B-3D are schematic views of a substrate at various stages of the process of FIG. 3A. In box 302, a via is etched into a layer of a substrate. The layer may be a dielectric layer, such as an oxide or nitride layer. The via will be etched by any of several known processes for etching vias in substrates, the exact process depending on the composition of the layer to be etched. FIG. 3B shows the substrate 350 having been so etched. Underlying layer 352 has dielectric layer 354 applied thereon, and a via 356 has been etched into the layer 354.

A conformal layer is formed over the substrate in box 304. In a process similar to those described above in connection with FIGS. 1A through 2H, the conformal layer covers the field region, sidewalls, and via bottom with step coverage between about 80% and about 120%. Any of the aforementioned processes may be used to deposit the conformal layer. In this embodiment, the conformal layer will have composition similar to that of the etched dielectric layer. The embodiment described by FIGS. 3A-3D contemplates the conformal layer remaining part of the finished device. Thus, in some embodiments the conformal layer will generally have dielectric constant similar to that of the dielectric layer.

FIG. 3C illustrates the substrate with a conformal layer 358 formed thereon. The conformal layer 358 reduces the width of the via 356 to form the reduced CD via 360. As described above in connection with FIGS. 1A through 2H, the width of via 356 is reduced by twice the thickness of the conformal layer 358.

In one embodiment, the conformal layer may be an oxide layer. A conformal layer of silicon oxide may be formed by a CVD or ALD process, with or without plasma, over an oxide dielectric layer, such as a low-k carbon containing dielectric layer. The dielectric layer may additionally be porous. The conformal oxide layer has sufficiently low dielectric constant and thickness to remain part of the device structure without adversely affecting the electrical properties of the device. In some embodiments, the conformal layer may have more or less than the stoichiometric ratio of oxygen to silicon. The conformal layer may thus have a ratio of oxygen to silicon ranging from about 1.8 to about 2.2.

In other embodiments, the conformal layer may be a nitrogen containing layer. Nitrogen may be useful to include in some embodiments because inclusion of nitrogen in silicon films increases their hardness and may impart barrier properties. The conformal layer may thus be a silicon nitride layer or a silicon oxynitride layer in some embodiments. Furthermore, in some embodiments, the conformal layer may be a fully nitrided silicon nitride layer, or may have a nitrogen content less than the stoichiometric ratio. For example, the ratio of nitrogen to silicon in a silicon nitride conformal layer used in the method 300 may be from about 0.7 to about 1.5.

Portions of the conformal layer are removed in box 306 to leave the exposed field region of the dielectric layer 354, the exposed bottom portion of the reduced CD via 360, and the remnant of the conformal layer 358 covering the side walls of the reduced CD via 360. Removal of the desired portions of the conformal layer may be accomplished through an anisotropic etching process tailored to the composition of the conformal layer. In an embodiment wherein the conformal layer is an oxide or nitride layer, a fluoride ion directional etch under electrical bias, as described herein above, will selectively etch the portions of the conformal layer covering horizontal surfaces of the substrate 350.

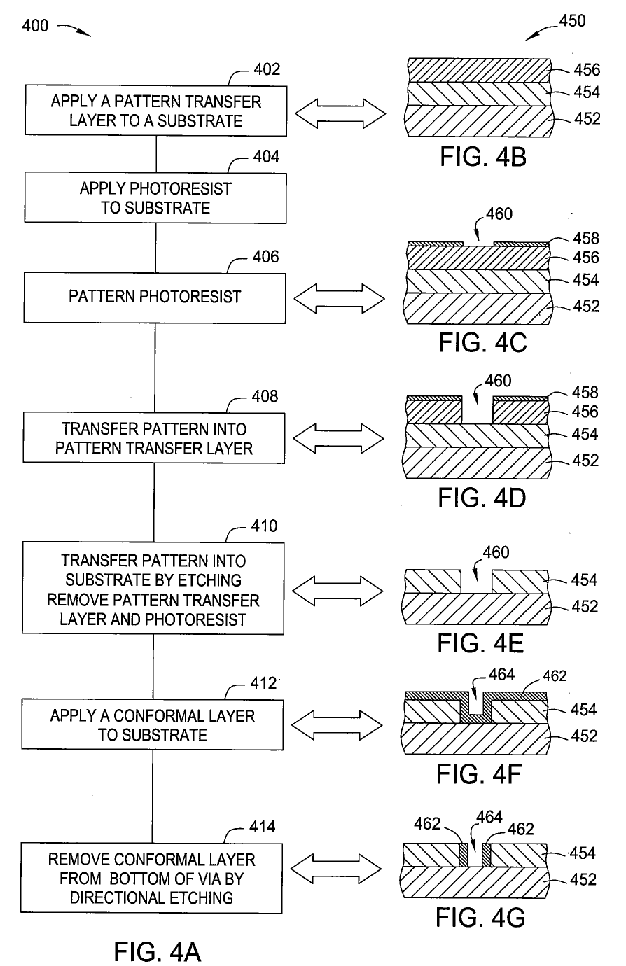

Embodiments of the invention provide another method of forming a via in a field region of a substrate. FIG. 4A is a flow diagram illustrating a method 400 according to another embodiment of the invention. FIGS. 4B-4G are schematic views of a substrate at various stages of the process of FIG. 4A. A substrate having a layer to be etched is provided to a processing chamber. In box 402, a pattern transfer layer is applied to an upper surface of the substrate. FIG. 4B shows a substrate 450 with base layer 452, etch layer 454, and pattern transfer layer 456. The pattern transfer layer may be of any composition resistant to the etch chemistry used to etch the layer 454. As described above in connection with FIGS. 2A-2H, a commonly used pattern transfer layer is amorphous carbon, formed by PECVD from hydrocarbon precursors.

A photoresist substantially similar to that described herein above is applied over the substrate in box 404 and patterned in box 406. FIG. 4C illustrates the substrate 450 at this stage of the method 400. The pattern transfer layer 456 is covered by the patterned photoresist 458, and the via 460 formed in the photoresist 458 exposes the pattern transfer layer 456 beneath.

The pattern is transferred into the pattern transfer layer in box 408, as illustrated in FIG. 4D, which shows via 460 extended into the pattern transfer layer 456. The process by which the pattern is transferred may be any of those described herein above, such as ashing or oxidative etching in the case of an amorphous carbon pattern transfer layer.

The pattern is then transferred into the substrate in box 410, as illustrated by FIG. 4E. The pattern transfer layer 456 is used as an etch mask to extend via 460 into the etch layer 454. The carbon layers have been removed by processes described herein above.

A conformal layer is applied to the substrate 450 in box 412 in a manner substantially similar to those described herein. FIG. 4F shows the substrate 450 with the conformal layer 462 applied thereto. The conformal layer 462 reduces the width of via 460 to form a reduced CD via 464. In this embodiment, the conformal layer is preferably compatible with the etch layer 454, so that it need not be removed from the via 460 prior to gap fill. The conformal layer may thus be a compatible dielectric, such as an oxide or nitride material, and may be deposited by methods described herein.

Portions of the conformal layer 462 are removed by directional or anisotropic etching in box 414. FIG. 4G shows the resulting structure with the conformal layer 462 removed from the bottom portion of the reduced CD via 464, but remaining along the sidewalls to preserve the reduced width.

In some embodiments, the pattern transfer layer may be a metal layer or a metal nitride layer. A metal or metal nitride layer is frequently used as an etch mask in damascene integration processes requiring very precise alignment of etched features. A conformal layer comprising an oxide or nitride, such as that described herein, is useful for reducing CD in such embodiments. The metal hardmask is etched to form a pattern, a conformal oxide or nitride layer formed thereon as described herein above, the portion covering the bottom of the pattern recess removed, and the reduced CD etch completed. The conformal layer may then be removed in the same stage as removal of the hardmask layer or in a different stage, after which gap fill may proceed.

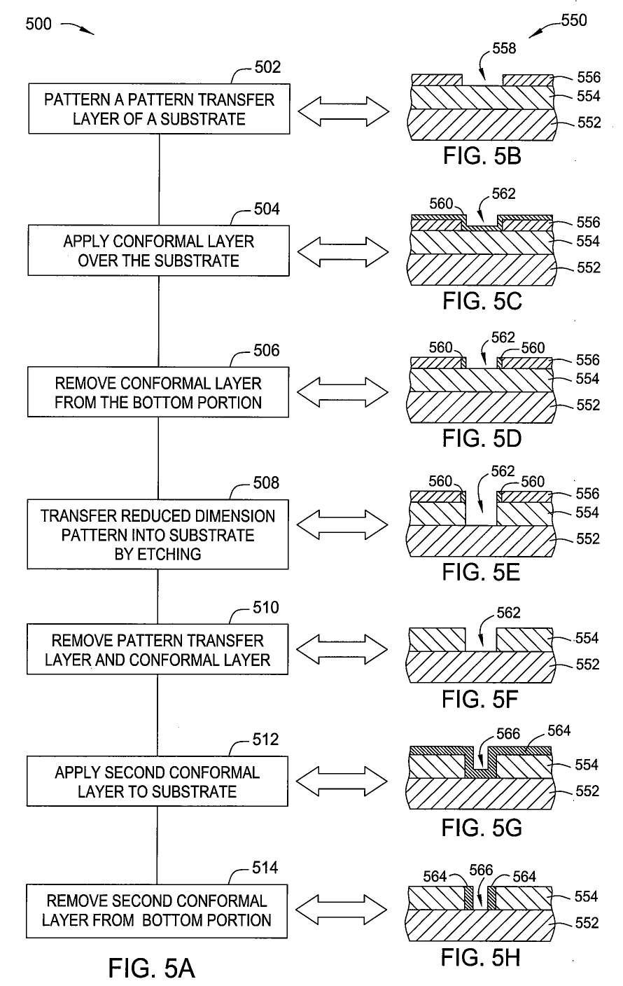

Some embodiments of the invention provide a method of patterning a dielectric layer formed on a substrate. FIG. 5A is a flow diagram illustrating a method 500 according to another embodiment of the invention. FIGS. 5B-5H are schematic views of a substrate at various stages of the method of FIG. 5A. A substrate to be etched is disposed within a processing chamber, and a pattern transfer layer having a pattern formed therein is deposited on the substrate in step 502. This may be accomplished as described above by depositing a photoresist layer, patterning, and transferring the pattern to the pattern transfer layer. FIG. 5B illustrates a substrate 550 at this stage of the process, with a base layer 552, a dielectric layer 554 to be etched, and a pattern transfer layer 556 having pattern recess 558 formed therein.

A conformal layer is formed over the substrate in box 504. The conformal layer may be formed using any of the methods described herein and may have composition similar to the conformal layers described herein above. The conformal layer will be formed to a thickness selected to reduce the width of pattern recess 558. FIG. 5C illustrates the substrate 550 having the conformal layer 560 formed thereon, resulting in a first reduced CD pattern recess 562.

The conformal layer is removed from the bottom portion of the reduced CD pattern recess in box 506. FIG. 5D illustrates the substrate 550 with the conformal layer 560 removed from the bottom portion of the reduced CD pattern recess 562. As described herein above, the conformal layer may be removed by any anisotropic means, such as reactive or non-reactive ion etching under bias, to expose the dielectric layer 554 beneath for etching.

The reduced CD pattern is transferred into the dielectric layer in box 508 through known etching processes. FIG. 5E illustrates the substrate with the reduced CD pattern recess 562 extended into the dielectric layer 554. The pattern transfer layer 556 and conformal layer 560 are then removed in box 510 to leave the patterned dielectric layer 554, as shown in FIG. 5F. The reduced CD pattern recess 562 formed in the dielectric layer 554 may be a narrow recess.

Further reduction of CD may be accomplished by applying a second formal layer to the substrate in box 512. As described above and illustrated in FIG. 5G, the second conformal layer 564 covers the field region of the dielectric layer 554 and the sidewalls and bottom portion of the reduced CD pattern recess 562. The CD is further reduced by the thickness of the conformal layer, resulting in a reduced CD via 566. As described above, a conformal layer used to reduce CD after etching will preferably be formed from a material compatible with the dielectric layer 554, and may be an oxide or nitride layer having low dielectric constant.

The second conformal layer 564 is removed from the bottom portion of the reduced CD via 566 in box 514, as illustrated in FIG. 5H. As described above in connection with FIGS. 3A-3D, it is contemplated that the second conformal layer deposited on the sidewalls of the reduced CD via 566 will remain part of the dielectric layer 554 in the completed device. Because the second conformal layer 564 is compatible with the dielectric layer 554, it has electrical properties generally adaptable to proper function within the device. Thus, CD reduction by application of conformal layers may be applied both before and after etching.

While the foregoing is directed to embodiments of the invention, other and further embodiments of the invention may be devised without departing from the basic scope thereof, and the scope thereof is determined by the claims that follow.

What is claimed is:

1. A method of reducing critical dimension of a recess having sidewalls and a bottom portion formed in a substrate having a field region, comprising:
applying a conformal layer over the field region, sidewalls, and bottom portion;
removing the conformal layer from the bottom portion by a directional etch process to expose the substrate;
etching the exposed substrate at the bottom portion; and
removing the conformal layer by a wet etch process.

2. The method of claim 1, wherein the conformal layer is a barrier layer.

3. The method of claim 1, wherein the recess is formed by patterning a pattern transfer layer of the substrate.

4. The method of claim 1, wherein the conformal layer is a nitrogen containing barrier layer.

5. The method of claim 1, wherein the directional etch process also removes the conformal layer from the field region.

6. The method of claim 1, wherein the conformal layer is a nitride layer.

7. The method of claim 1, wherein the conformal layer is deposited by a PECVD process.

8. The method of claim 1, wherein the conformal layer comprises elements selected from the group consisting of boron, silicon, nitrogen, oxygen, and combinations thereof.

9. The method of claim 1, wherein the conformal layer comprises a material having a low etch rate when exposed to etchants selected to etch the substrate.

10. The method of claim 1, wherein removing the conformal layer by a wet etch process comprises exposing the conformal layer to an aqueous solution.

11. The method of claim 1, wherein the substrate comprises a dielectric layer and a pattern transfer layer.

12. The method of claim 11, wherein the recess is formed by transferring a pattern from the pattern transfer layer to the dielectric layer.

13. The method of claim 12, further comprising removing the pattern transfer layer.

14. The method of claim 1, wherein the directional etch process comprises forming a plasma from an etchant gas and applying an electrical bias to the substrate.

15. A method of forming a via in a field region of a substrate, comprising:
patterning a layer formed on a surface of the substrate to form a recess having sidewalls and a bottom portion;
reducing the width of the recess by applying a conformal film over the layer;
forming a reduced critical dimension area by removing the conformal film from the bottom portion of the recess to expose a portion of the substrate; and
etching the reduced critical dimension area to form the via.

16. The method of claim 15, wherein the layer is an amorphous carbon layer.

17. The method of claim 15, wherein the conformal film is a nitrogen containing film.

18. The method of claim 15, wherein removing the conformal film comprises exposing the film to a plasma of an etchant gas and applying an electrical bias to the substrate.

19. The method of claim 15, further comprising removing the conformal film by a wet etch process.

20. The method of claim 19, wherein removing the conformal film by a wet etch process comprises exposing the conformal film to an aqueous solution.

21. The method of claim 20, wherein the aqueous solution comprises an oxidizing solution.

22. A method of patterning a dielectric layer formed on a substrate, comprising:
forming a pattern transfer layer over the dielectric layer;
patterning the pattern transfer layer by applying a photoresist, patterning the photoresist, and etching the pattern into the pattern transfer layer to form a recess having a bottom portion;
depositing a first conformal layer over the pattern transfer layer;
removing the first conformal layer from the bottom portion of the recess to expose the dielectric layer;
etching the exposed portion of the dielectric layer to form a narrow recess;
removing the pattern transfer layer and the conformal layer;
depositing a second conformal layer over the substrate; and
removing the second conformal layer from the bottom portion of the narrow recess.

23. The method of claim 22, wherein the first conformal layer is a nitrogen containing layer.

24. The method of claim 23, wherein the second conformal layer is a oxygen containing layer.
